(19) United States
(12) Patent Application Publication
(10) Pub. No.: US 2005/0286283 A1
(43) Pub. Date: Dec. 29, 2005

(54) Method and system for expanding flash storage device capacity

(76) Inventors: Sun-Teck See, San Jose, CA (US); Horng-Yee Chou, Palo Alto, CA (US); Charles C. Lee, Sunnyvale, CA (US)

Correspondence Address: SAWYER LAW GROUP LLP, P.O. Box 51418, Palo Alto, CA, 94303, US

(21) Appl. No.: 10/881,037

(22) Filed: Jun. 29, 2004

(51) Int. Cl. G11C 5/06

(52) U.S. Cl. 365/63

(57) ABSTRACT

A Flash storage device is disclosed. The Flash storage device comprises a plurality of memories and a printed circuit board coupled to the plurality of memories. The PCB is extended beyond a predetermined dimension to accommodate the plurality of memories. By extending the length and/or the width of the PCB, additional memories can be added to the PCB, thereby adding to the memory capacity of the device.

### FIELD OF THE INVENTION

The present invention relates generally to memories and more particularly to a system and method for expanding the capacity of Flash storage devices.

### BACKGROUND OF THE INVENTION

The nature of non-volatile, vibration-free, small size and low power consumption has made the Flash memory an excellent component to be utilized in various Flash storage devices. Flash storage devices are widely used as memory storage for computer and consumer system products such as notebook, desktop computer, set top box, digital camera, mobile phone, PDA and GPS etc. The increasing demand for more storage in these products has driven the need to expand the capacity of the Flash storage devices.

There are two types of Flash storage devices. The first type has a pre-defined mechanical dimension. This type includes: (a) Secure Digital (SD) card, (b) Multi Media Card (MMC), (c) Memory Stick (MS) card, (d) Compact Flash (CF) card, (e) Express Flash card, (f) Serial ATA Flash disk, (g) IDE Flash disk, (h) SCSI Flash disk, etc.

The second type of Flash storage devices has no pre-defined physical dimension, which includes USB Flash disk, Disk On Module (DOM), MP3 player etc. However, corresponding based upon the need for the system compactness, it is generally desirable to make this type of Flash storage device as small in size and as high in capacity as possible.

Space constraints and available Flash memory density are the major obstacles in expanding the capacity of the Flash storage devices. FIG. 1 illustrates top, bottom, short side lateral and long side lateral views of a secure digital (SD) card 10. The SD card 10 is defined with a form factor of 32×24×2.1 mm (length×width×thick). This fixed dimension restricts the number of components populated on a printed circuit board (PCB) 12. For instance, if TSOP type of Flash memory is used, only a Flash memory chip 14 and a Flash controller 16 can be placed in the space constraint. The available Flash memory density further limits the overall SD card capacity. For instance, if the highest Flash memory is 4 Gb, the maximum SD card capacity is then limited to 512 MB.

A Flash memory die is the basic element of Flash memory. A typical Flash memory chip comprises a Flash memory die mounted on a substrate within an enclosure and the electrical signals are bonded out to the metal contacts of the package. FIG. 2 illustrates a Flash memory chip 50 in a thin, small out-line package (TSOP). The popular package types for Flash memory chip are TSOP (Thin Small Out-line Package), WSOP (Very Very Thin Small Out-line Package) and BGA (Ball Grid Array), etc. For the purposes of this application, Flash memory will be used to describe both a Flash memory die and a Flash memory chip.

Besides power and ground, a Flash memory includes the following electrical signals:

(a) Bidirectional signals: I/O (Input/Output) bus. It is a bidirectional bus. Flash memory uses this bus to input command, address and data, and to output data during read operation. Multiple Flash memories can share this bus with a Flash controller.

(b) Common Input Control Signals: ALE (Address Latch Enable), CLE (Command Latch Enable), RE- (Read Enable), WE- (Write Enable), WP- (Write Protect). Driven by Flash controller for various operations to Flash memory. These signals are shared among multiple Flash memories connected to a single I/O bus.

(c) Exclusive Input Control Signal: CE- (Chip Enable). Driven by Flash memory controller to enable the Flash memory for access. To ensure only one of them is enabled at a time, each Flash memory is connected to a unique CE-.

(d) Output Status Signals: R/B- (Ready/Busy-). Driven by Flash memory when it is busy, not ready to accept command from the Flash controller. It is an open-drain signal that can be shared among multiple Flash memories connecting to a single I/O bus.

The typical functional block diagram of a Flash storage device 80 is shown in FIG. 3. It comprises a Flash controller 82 and at least a Flash memory 84. One end of the Flash controller 82 interfaces to the host while the other end controls the access to Flash memory 84.

In many instances, due to cost and pin count considerations, a Flash controller has a limited number of chip enable signals. This limitation imposes a restriction on capacity expansion.

Furthermore, as the demand for Flash storage devices has increased, a shortage of certain types of Flash memory occurs during the course of a year. Flash types of the most popular density are typically out of supply during the peak seasons.

Accordingly it is desirable to provide ways to expand Flash storage devices. The present invention addresses such a need.

### SUMMARY OF THE INVENTION

A Flash storage device is disclosed. The Flash storage device comprises a plurality of memories and a printed circuit board coupled to the plurality of memories. The PCB is extended beyond a predetermined dimension to accommodate the plurality of memories. By extending the length and/or the width of the PCB, additional memories can be added to the PCB, thereby adding to the memory capacity of the device.

### BRIEF DESCRIPTION OF THE DRAWINGS

FIG. 1 illustrates a top and bottom view of a secure digital card.

FIG. 2 shows a Flash memory chip in TSOP package.

FIG. 3 illustrates a typical block diagram inside a Flash storage device.

FIG. 4A depicts a typical PCB population of a SD card shown in FIG. 1.

FIG. 4B shows an extended PCB with single side population.

FIG. 4C shows an extended PCB with double sided population.

FIG. 4D shows an extended PCB with stacked population.

FIG. 4E shows the top view of a Secure Digital Card with extended PCB.

### DETAILED DESCRIPTION OF THE INVENTION

The present invention relates generally to memories and more particularly to a system and method for expanding the capacity of Flash storage devices. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown but is to be accorded the widest scope consistent with the principles and features described herein.

5. Extended PCB

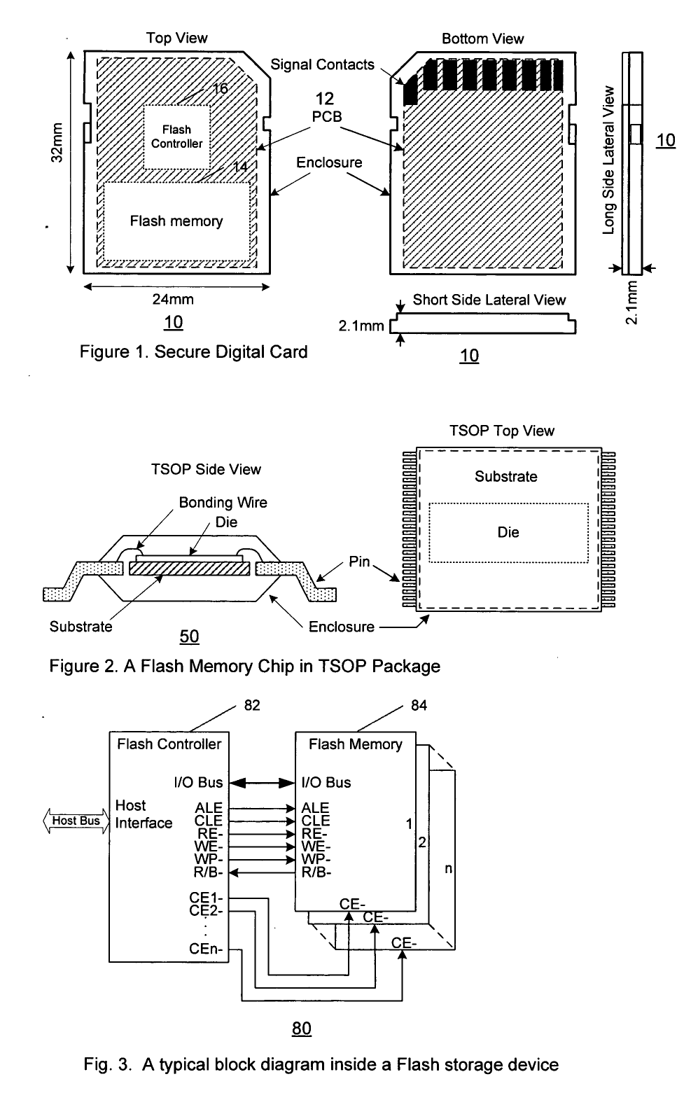

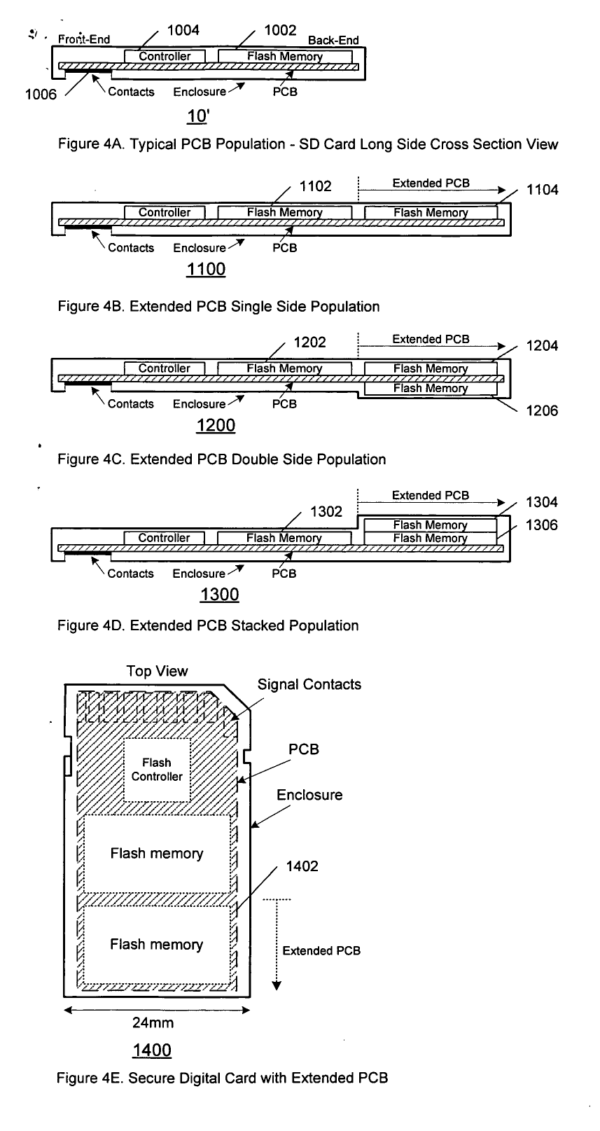

Flash memories can be added to the Flash storage devices with pre-defined dimension by extending the length and/or the width of the PCB. FIG. 4A depicts a typical PCB population of Flash storage device and as the SD card 10′ as shown in FIG. 1. Within the fixed enclosure, the PCB has limited space, in which only one Flash memory chip 1002 is allowed along with the Flash controller 1004. When the SD card 10′ is inserted into the host system, the front-end is coupled to contacts 1006 is within the host system (such as a digital camera) for connectivity while the back-end is at the opening of the host system. Therefore the back-end allows for the for PCB extension to accommodate more Flash memories to expand the capacity of the device.

FIG. 4B shows an extended PCB 1100 with single side population. Extra Flash memories 1104 can be installed on the one of the sides (top or bottom) of the PCB.

FIG. 4C shows an extended PCB 1200 with double side population. Extra Flash memories 1204-1206 can be installed on both of the sides of the PCB 1200.

FIG. 4D shows an extended PCB 1300 with stacked population. Extra Flash memories 1304-1306 can be stacked together and installed on either side or both sides of the PCB. The stacking can be two or more than two Flash memories.

FIG. 4E shows the top view of a Secure Digital Card 1400 with extended PCB 1402.

The above figures show some examples of the extended PCB. The Flash memories can be Flash memory chips or Flash memory dies. The PCB can be further extended at the back-end to accommodate more Flash memory chips or dies. This technique resolves the space constraint of the Flash storage devices with pre-defined dimension, including but not limited to SD card, MMC card, MS card, CF card and Express Flash card.

Although the present invention has been described in accordance with the embodiments shown, one of ordinary skill in the art will readily recognize that there could be variations to the embodiments and those variations would be within the spirit and scope of the present

1. A Flash storage device comprising:
a plurality of memories; and
a printed circuit board PCB coupled to the plurality of memories wherein the PCB is extended beyond a predetermined dimension to accommodate the plurality of memories.

2. The Flash storage device of claim 1 wherein the plurality of memories are coupled to one side of the PCB.

3. The Flash storage device of claim 1 wherein the plurality of memories are coupled to both sides of the PCB.

4. The Flash storage device of claim 1 wherein the plurality of memories are coupled to the PCB in a stacked manner.

5. The Flash storage device of claim 1 wherein the plurality of memories are coupled to the PCB in any combination to one side of the PCB, to both sides of the PCB and coupled in a stacked manner to the PCB

6. The Flash storage device of claim 1 wherein the plurality of memories comprise Flash memories.

7. The Flash storage device of claim 6 wherein the plurality of Flash memories comprise a plurality of Flash memory dies.

8. The Flash storage device of claim 6 wherein the plurality of Flash memories comprise a plurality of Flash memory chips.

9. The Flash storage device of claim 1 wherein the Flash storage device comprises any of a Secure Digital (SC) card, Multi Media card (MMC), Memory Stick (MS) card, Compact Flash (CF) card and Express Flash card.

10. A Secure Digital (SC) card comprising:
a plurality of Flash memories; and
a printed circuit board (PCB) coupled to the plurality of Flash memories, wherein the PCB is extended beyond the predetermined dimension of a secure digital card to accommodate the plurality of Flash memories.
